(19) United States
(12) Patent Application Publication
(10) Pub. No.: US 2017/0121814 A1
(43) Pub. Date: May 4, 2017

(54) Apparatus and Method for Delivering a Gaseous Precursor to a Reaction Chamber

(71) Applicant: IMEC VZW, Leuven (BE)

(72) Inventor: Matty Caymax, Heverlee (BE)

(73) Assignee: IMEC VZW, Leuven (BE)

(21) Appl. No.: 15/334,668

(22) Filed: Oct. 26, 2016

(30) Foreign Application Priority Data
Nov. 2, 2015 (EP) 15192571.6

(51) Int. Cl. C23C 16/448; C30B 25/14; C23C 16/455

(52) U.S. Cl. CPC C23C 16/4482; C23C 16/45544; C23C 16/45553; C30B 25/14

(57) ABSTRACT

The disclosure relates to an apparatus and method for delivering a precursor to a reaction chamber. One example embodiment is an apparatus for delivering a precursor to a reaction chamber. The apparatus includes a recipient configured to hold a quantity of the precursor in a solid or liquid state at a given temperature and pressure so as to vaporize the precursor. The apparatus also includes a carrier gas supply line, configured to supply a carrier gas to the recipient. Further, the apparatus includes a gas mixture transport line configured to transport a mixture of the carrier gas and a vapor of the precursor out of the recipient. The glass mixture transport line extends between the recipient and an outlet section of the gas mixture transport line.

### CROSS-REFERENCE TO RELATED APPLICATIONS

The present application is a non-provisional patent application claiming priority to European Patent Application No. EP 15192571.6, filed Nov. 2, 2015, the contents of which are hereby incorporated by reference.

### FIELD OF THE DISCLOSURE

The present disclosure relates to the production and transport of gaseous precursors, to be used as reagents in a reaction chamber. One possible field of application is the delivery of precursor gas to a substrate placed in a reaction chamber, in order to deposit a layer on the substrate. The disclosed embodiments may be applicable to processes such as Chemical Vapor Deposition (CVD), Atomic Layer Deposition (ALD), and Atomic Layer Epitaxy (ALE).

### BACKGROUND

CVD, ALD, and similar deposition processes use chemical precursors, which can be permanent gases, liquids, or solids. In the two latter cases, the precursor may be volatilized (the gas phase of the precursor is commonly called “vapor”) in order to be able to inject it into the reaction chamber of a reactor. This is possible for precursors with a rather high vapor pressure at room temperature, for example trimethylaluminium (TMA) which has a vapor pressure of about 1333 Pa at room temperature. In this case, the vapor may be drawn off from a certain amount of TMA in a closed vessel and transported with an inert carrier gas, e.g. argon (“vapor draw system”). Alternatively, a “bubbler arrangement” may be used in which an inert carrier gas is bubbled through a liquid or molten precursor so that the carrier gas becomes loaded with the precursor, which can as such be transported into the reactor. The partial pressure of the precursor gas in this mixture is equal to the vapor pressure of the precursor at room temperature. The relatively high vapor pressure enables a sufficient amount of the precursor gas to be supplied to the reactor for deposition. The “vapor draw” approach may be used in cases involving solid precursors.

In case the precursor has a very low vapor pressure at room temperature, the vapor pressure may be raised by heating. This again can be done in vapor draw or bubbler mode. For some precursors however, very high temperatures may be used, for example in the case of HfCl₄ (Hafnium Tetrachloride), which has a vapor pressure of about 133.3 Pa at 170° C. Working with lower vapor pressures would reduce the amount of precursor that can be injected into the reactor which is practically not workable. A potential drawback in these cases is that the gas mixture may be maintained at a high temperature at any moment until its injection into the reactor. Any cold spot on the way between the vaporizer system and the reactor can result in condensation, so that no gaseous precursor reaches the reactor. Furthermore, condensation may lead to clogging of controlling components (valves, mass flow controllers, etc.) or at restrictions in the piping system. This can be a major limitation in cases where the temperature is above the critical operating temperature of conventional construction and sealing materials such as O-rings, especially in complex constructions such as showerheads or injection systems including sensitive metering valves. Many constructions cannot tolerate temperatures above roughly 125° C.

A possible resolution may include a dilution of the carrier/precursor mixture, leading to a reduction of the precursor's partial pressure, so that the mixture may be transported at lower temperatures without the risk of condensation. This technique, however, may use the supply of a dilution gas through suitable regulated supply lines, with the supply lines kept at the higher temperature over at least a given distance. It can therefore be technically complex and expensive.

Another potential solution involves the reduction of the pressure of the gas mixture by releasing a portion of the mixture into the atmosphere, for example by venting. This, however, may not be economical, as an important amount of the precursor is wasted.

### SUMMARY

Disclosed embodiments relate to an apparatus, an installation and a method, as disclosed in the appended claims, wherein the above-described drawbacks may be overcome. Some embodiments relate to an apparatus and method for delivering a gaseous precursor to a reaction chamber, wherein a mixture of a carrier gas and a precursor vapor is transported from a recipient where the precursor is vaporized, to the reaction chamber. A gas mixture transport line coupled to the recipient is maintained at the same temperature as the recipient and comprises a pressure control device configured to maintain the pressure upstream of the device at a pre-defined level, before releasing the mixture to an area at a lower pressure than the predefined level, while remaining at the same temperature as the recipient. The controlled pressure drop leads to a reduction of the precursor vapor's partial pressure in the mixture, allowing the supply to the reaction chamber to be delivered at a lower temperature without condensation of the precursor. A diluent gas flow may be added to the carrier/precursor mixture prior to the passage through the pressure control device, which allows an additional reduction of the partial pressure.

Some embodiments relate to an apparatus for delivering a gaseous precursor to a reaction chamber, the apparatus comprising:
a recipient for holding a quantity of the precursor in a solid or liquid state at a given temperature and pressure so as to vaporize the precursor,
a carrier gas supply line, for supplying a carrier gas to the recipient,
a gas mixture transport line for transporting a mixture of the carrier gas and a vapor of the precursor out of the recipient, the gas mixture transport line extending between the recipient and an outlet section of the gas mixture transport line, the outlet section being configured to be coupled to a supply line, external to the apparatus, for supplying the mixture to the reaction chamber,
   wherein the recipient and the gas mixture transport line are configured to be maintained at a single predefined temperature, and wherein the gas mixture transport line comprises a pressure control device configured to maintain the pressure upstream of the device at a predefined level. The pressure control device is configured to maintain the upstream pressure without releasing a portion of the mixture into the atmosphere.

According to an example embodiment, the pressure control device may provide the sole reduction of the partial pressure of the gas mixture in the apparatus, i.e. the apparatus comprises no additional way of reducing the pressure of the gas mixture. In this embodiment, therefore, the apparatus comprises no means for diluting the gas mixture by mixing it with a diluent gas.

According to another embodiment, the apparatus further comprises a diluent gas supply line, for supplying a diluent gas to the gas mixture transport line, wherein the diluent gas supply line joins the gas mixture transport line at a location upstream of the pressure control device.

According to specific embodiments, the apparatus comprises a furnace comprising the recipient, the gas mixture transport line and at least a portion of the carrier gas supply line and, if applicable, at least a portion of the diluent gas supply line. According to an embodiment, the pressure control device is a back pressure regulating valve.

Some embodiments relate to an installation for depositing a layer on a substrate by chemically reacting a gaseous precursor with chemical elements of the substrate, wherein the installation comprises:
an apparatus as described herein,
a carrier gas/precursor vapor mixture supply line coupled to the outlet section of the gas mixture transport line,
a deposition reactor comprising a reaction chamber coupled to the carrier gas/precursor vapor mixture supply line.

Some embodiments relate to a method for delivering a gaseous precursor to a reaction chamber, the method comprising the steps of:
heating a precursor in a recipient to a heating temperature, wherein the heating temperature is determined on the basis of a pre-determined vapor pressure of the precursor and vaporizing the precursor at the heating temperature,
supplying a predefined flow of a carrier gas to the recipient,
transporting a mixture of carrier gas and precursor vapor away from the recipient through a gas mixture transport line, while maintaining the gas mixture transport line at the heating temperature, wherein the gas mixture transport line is provided with a pressure control device configured to maintain the pressure upstream of the device at a predefined level,
maintaining the total pressure in the gas mixture transport line upstream of the pressure control device at a predefined level,
reducing the total pressure of the mixture to a value less than the predefined level, downstream of the pressure control device, thereby reducing the partial pressure of the precursor vapor in the mixture,
transporting the mixture towards the reaction chamber, while maintaining the mixture at a temperature less than the heating temperature, and above the condensation temperature of the precursor vapor in the mixture.

According to an embodiment, a diluent gas flow is supplied at a location in the gas mixture transport line upstream of the pressure control device, so that a diluted mixture flows through the device.

According to specific embodiments, the precursor is HfCl₄ or MoCl₅ and the carrier gas is chosen from the group consisting of Ar, He and H₂.

### BRIEF DESCRIPTION OF THE FIGURES

FIG. 1 is a schematic illustration of an apparatus, according to example embodiments.

FIG. 2 is a schematic illustration of an apparatus, according to example embodiments.

### DETAILED DESCRIPTION

Various features will be described with respect to particular example embodiments and with reference to certain drawings, but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice.

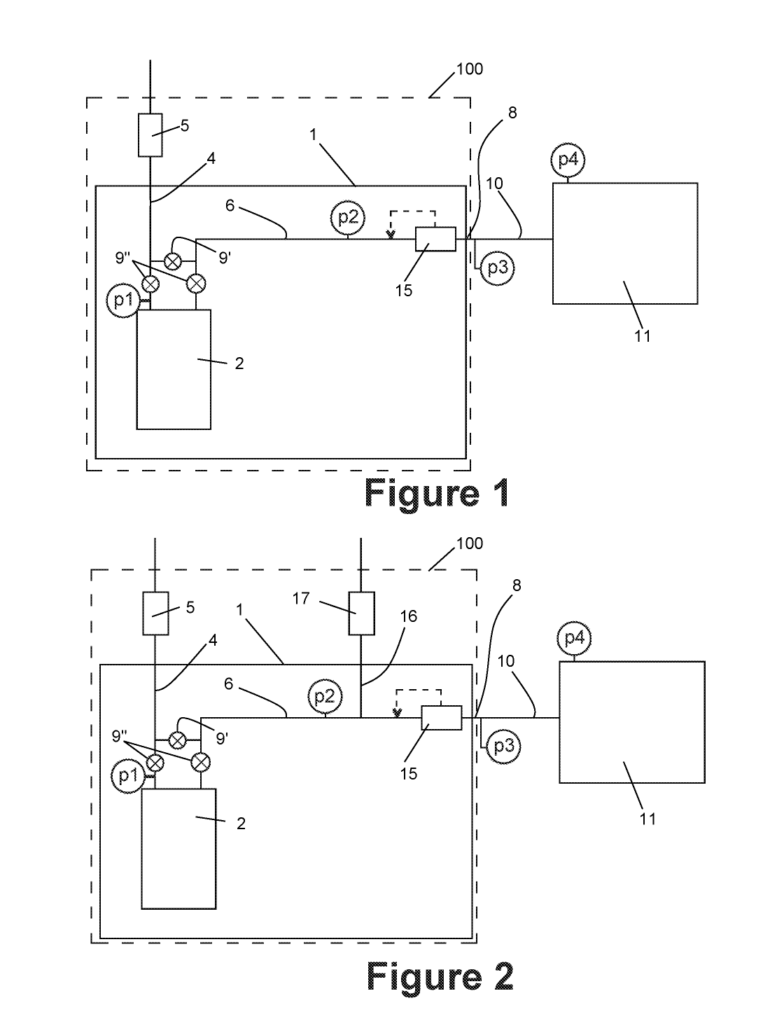

The apparatus and the method of example embodiments will be described hereafter with reference to the enclosed drawings. The drawings are schematic only and may not be drawn to scale. FIG. 1 shows a first example embodiment of an apparatus 100, coupled to the reaction chamber 11 of a deposition reactor. The apparatus 100 comprises a furnace 1. Inside the furnace is a canister 2 in which a precursor in the solid state is loaded, the precursor being for example in the form of a powder loaded into the canister. The canister may be any type of canister applied in presently known sublimation systems. The temperature in the furnace 1 and thereby in the canister 2 is raised to a value T1 at which the vapor pressure of the precursor is at a predefined level sufficient to result in sufficient vapor production, e.g. a vapor pressure of about 133.3 Pa. The precursor is vaporized at this temperature in the canister, by reducing the pressure to the vapor pressure, so that the vapor is in equilibrium with the solid precursor at the predefined vapor pressure.

A given mass flow of an inert carrier gas is then supplied to the canister 2 through carrier gas supply line 4, which is provided with a mass flow controller 5. The mass flow controller may be a part of the apparatus 100, as shown in the drawings, or it may be external to the apparatus. The carrier gas flows through the canister and draws away the precursor vapor so that a mixture of carrier gas and precursor vapor flows out of the canister into a gas mixture transport line 6 coupled to the canister 2. The gas mixture transport line 6 is included in the furnace 1, i.e. the canister 2 and the transport line 6 are configured to be maintained at a single predefined temperature T1. The gas mixture transport line 6 extends between the canister 2 and an outlet section 8 of the transport line 6, which corresponds to the outlet section of the furnace 1. In other words, upstream of the outlet section 8, the temperature is maintained at T1 whereas downstream of the outlet section 8, the temperature is not maintained at T1 (for example, it may be room temperature or any temperature less than T1). The valves 979″ are configured to allow installation and exchanging of the canister 2. When the apparatus 100 is operational, the middle valve 9′ is closed and the left and right valves 9″ are open.

At the inlet of the canister 2, the total pressure is p1. In the canister 2, a gas mixture of carrier gas and precursor vapor is formed, wherein the partial pressure of the precursor vapor in the mixture substantially remains at the above-described vapor pressure of the particular precursor type that is being used. Downstream of the canister 2, the total pressure drops to a value p2 less than p1 due to the flow resistance inside the canister 2. The value p1-p2 depends on the carrier gas mass flow injected into the canister (as controlled by the mass flow regulator 5), and the geometry and size of the canister 2.

According to the embodiment illustrated in FIG. 1, the total pressure is reduced in a controlled manner from a pre-defined set value p2 to a lower value p3, while maintaining the gas mixture at the temperature T1 of the furnace 1. For this purpose, a pressure control device 15 is provided in the gas mixture transport line 6, upstream of the exit section 8 of the transport line 6. It is a device which allows passage of a fluid while maintaining the pressure of the fluid upstream of the device at a predefined value, and without releasing a portion of the fluid (i.e. without venting). According to the embodiment illustrated in FIG. 1, this device is a back pressure regulating (BPR) valve. A BPR valve may be closed and opens when the inlet pressure exceeds a predefined value, for example by working against a spring force. In this way, the inlet pressure is maintained at the predefined value. This may be contrary to a normal pressure regulating valve, which may be open, and closes only when the outlet pressure exceeds a given value.

In the apparatus, the back pressure regulating (BPR) valve 15 thus controls the pressure p2 to a pre-defined value (symbolized by the arrow). The geometry and material of the gas mixture transport line 6 can be chosen such that a pressure drop due to this transport line itself is negligible, i.e., the pressure p2 is substantially the same anywhere in line 6, up to the back pressure regulating valve 15. By controlling the pressure p2 to a pre-defined set value, this pressure p2 also determines, together with the carrier gas flow, the pressure p1 at the inlet of the canister.

Downstream of the furnace 1, a carrier/precursor mixture supply line 10 is coupled to the outlet section 8 of the gas mixture transport line 6. Through the supply line 10, the gas mixture flows to the reaction chamber 11 of a deposition reactor, which may be a CVD or ALD reactor. The supply line 10 is therefore not a part of the furnace 1 and may be for example at room temperature. The pressure p4 in the reactor is pre-defined based on the conditions used in the deposition process.

The total pressure p3 at and directly beyond the outlet section 8 of the gas mixture transport line 6 is defined by the pre-defined pressure p4 in the reaction chamber and the pressure loss Δp in the supply line 10, which itself depends on the carrier gas mass flow and the geometry (diameter and length for a cylindrical pipe plus any restrictions presented by bends or gas flow controlling devices such as valves or the like) of the supply line 10. The flow characteristics (e.g. geometry, materials, etc.) of the BPR valve 15, the outlet section 8 and supply line 10 are such that the value p3 is substantially not influenced by the value of p2. In other words, the gas mixture is released by the pressure control device 15 into an area (the inlet of the supply line 10), which is at a lower pressure than the predefined set value p2. The pressure drop from the set value p2 to p3 results in a drop in the precursor's partial pressure by a factor p3/p2, while the precursor/carrier mixture is maintained at the high temperature T1. Within the physical limits of the various components of the installation, a greater set value of the pressure p2 thereby results in a more important decrease of the precursor's partial pressure.

The lower partial pressure of the precursor vapor corresponds to the vapor pressure for the precursor at a condensation temperature T2 that is less than the temperature T1 of the furnace. When the mixture then leaves the furnace 1, condensation of the precursor gas is avoided as long as the temperature of the supply line 10 is greater than or equal to T2. If the reduced condensation temperature T2 is 20° C. or less, the supply line 10 can be maintained at room temperature without danger of condensation of the precursor gas. The decrease in partial pressure takes place before the gas mixture leaves the furnace 1, i.e. while the mixture is maintained at a given high temperature T1.

It may be a characteristic that the pressure control device 15 is included in the mixture transport line 6, i.e. in a portion of the inventive apparatus that is configured to be maintained at the same temperature as the recipient 2 in which the precursor is vaporized. This characteristic enables a partial pressure reduction prior to the lowering of the temperature of the mixture, using the pressure control device. The use of the pressure control device in this way makes it possible to supply the precursor gas at lower temperatures, without necessitating a dilution of the carrier/precursor mixture. Nevertheless, dilution of the mixture can be additionally applied in combination with the pressure control device, as explained in the next paragraph.

According to a further embodiment illustrated in FIG. 2, a diluent gas is added to the gas mixture transport line 6 via a second supply line 16 provided with a second mass flow controller 17 (which may or may not be a part of the apparatus 100). The diluted gas mixture then flows through the back pressure control valve 15. The addition of the diluent gas causes a reduction of the partial pressure of the precursor gas in the mixture by a factor equal to the ratio of the carrier gas flow (as controlled by the first mass flow controller 5) to the sum of the carrier gas flow and the diluent gas flow (the latter controlled by the second mass flow controller 17).

The subsequent pressure drop from p2 to p3 as described with reference to FIG. 1 causes an additional decrease of the partial pressure of the precursor gas by a factor p3/p2. This double decrease of the partial pressure makes it possible to bring down this partial pressure to lower levels compared to the embodiment of FIG. 1.

Instead of a sublimation canister 2, a bubbler may be applied when the precursor is in liquid form. The diluent gas may be the same as the carrier gas, or it may be different. Like the carrier gas, the diluent gas is however inert with respect to the precursor gas. Various embodiments may not be limited to an apparatus wherein the canister and the gas mixture transport line 6 are mounted in a furnace 1. Other ways of maintaining the canister and the gas mixture transport line 6 at the same temperature may be applied.

Additional embodiments relate to the installation as shown in FIGS. 1 and 2 as a whole, i.e. including the apparatus 100, the supply line 10 and a deposition reactor comprising the reaction chamber 11. Further embodiments relate to a method for delivering a gaseous precursor to a reaction chamber. The method has been described above with reference to the drawings. A more general description of the method is as follows:
heating a precursor in a recipient 2 so as to vaporize the precursor, wherein the heating temperature is determined on the basis of a pre-determined vapor pressure of the precursor, the vapor pressure being sufficient to produce a significant supply of precursor to the reaction chamber. As stated before in this description, “heating the precursor so as to vaporize the precursor” is to be understood as “heating the precursor to a heating temperature that is determined on a pre-determined vapor pressure and vaporizing the precursor at the heating temperature.”
supplying a predefined flow of a carrier gas to the recipient 2, as may be controlled by a mass flow controller 5,
transporting a mixture of carrier gas and precursor vapor away from the recipient 2 through a gas mixture transport line 6, while maintaining the gas mixture transport line at the heating temperature, wherein the gas mixture transport line is provided with a pressure control device 15, configured to maintain the pressure upstream of the device at a predefined level. The pressure control device may be a backpressure regulating valve,
maintaining the total pressure in the gas mixture transport line upstream of the pressure control device 15 at a predefined level p2, by applying a corresponding setting to the pressure control device 15,
reducing the total pressure of the mixture to a value p3 lower than the predefined level, downstream of the pressure control device 15, thereby reducing the partial pressure of the precursor vapor in the mixture. The pressure p3 may be determined by a pre-defined pressure p4 in the reaction chamber 11 and by the pressure loss in a supply line 10 towards the reaction chamber,
transporting the mixture towards the reaction chamber 11, while maintaining the mixture at a temperature less than the heating temperature, and above the condensation temperature of the precursor vapor in the mixture.

According to an example embodiment of the method, a diluent gas is added to the gas mixture transport line 6 upstream of the pressure control device 15, so that a diluted mixture flows through the device.

### EXAMPLES

The effectiveness of the apparatus and method of various embodiments is further illustrated by the following examples. Table 1 gives values for a number of the parameters described above. Some parameters are common to all the examples: the length and diameter of the supply line 10 are 2 m and 1.27 cm, respectively. The pressure loss over the supply line 10 is calculated using standard formulae. The diluent gas is the same as the carrier gas. The pressure drop over the canister is estimated to be 799.8 Pa. Values in bold type are pre-defined. The other values are derived from those predefined values in the manner described above or by known formulas. The examples are related to HfCl₄ and MoCl₅ as example precursors. These precursors have a vapor pressure of about 133.3 Pa at elevated temperatures of 170° C. and 120° C. respectively, whereas at room temperature, the vapor pressures are too low to be of interest in a deposition process. The flow rates in table 1 are expressed in standard liters per minute (slm). The SI unit for this parameter is Pa×m³/s with 1 slm=1.69 Pa×m³/s.

TABLE 1

| | | | | | |
|---|---|---|---|---|---|
| Precursor type | HfCl₄ | HfCl₄ | MoCl₅ | MoCl₅ | MoCl₅ |
| Temperature in | 170 | 170 | 120 | 120 | 120 |
| furnace (° C.) | | | | | |
| Precursor Partial | 125.3 | 125.3 | 134.4 | 134.4 | 134.4 |
| pressure in canister | | | | | |
| p_{c} (Pa) | | | | | |
| Carrier gas/diluent | Ar | H₂ | Ar | He | H₂ |
| gas | | | | | |
| Carrier gas flow | 0.15 | 0.15 | 0.15 | 0.15 | 0.15 |
| (slm) F1 | | | | | |
| Diluent gas flow | 5 | 20 | 1 | 5 | 0 |
| (slm) F2 | | | | | |
| p2 (Pa) | 2666 | 13330 | 2666 | 2666 | 13330 |
| p1 (Pa) = p2 + | 3465.8 | 14129.8 | 3465.8 | 3465.8 | 14129.8 |
| 799.8 | | | | | |
| Δp supply line (Pa) | 559.9 | 66.7 | 104 | 479.9 | 13.3 |
| p4 (Pa) | 266.6 | 266.6 | 266.6 | 266.6 | 266.6 |
| p3 (Pa) = p4 + Δp | 826.5 | 333.3 | 370.6 | 693.2 | 279.9 |
| Precursor Partial | 1.2 | 0.03 | 2.4 | 1.1 | 2.8 |
| pressure at furnace | | | | | |
| exit (Pa) | | | | | |
| Precursor | 104.4 | 63.3 | 23.4 | 17.6 | 24.4 |
| Condensation | | | | | |
| temperature at | | | | | |
| furnace exit (° C.) | | | | | |

The precursor partial pressure at the furnace exit is calculated as:

$${p}_{c} * \frac{F 1}{F 1 + F 2} * \frac{{p}_{3}}{{p}_{2}}$$

These calculations show that the condensation temperature can be significantly reduced by a suitable choice of a number of parameters, most notably the carrier gas type, the diluent mass flow rate, and the pressure p2 which in turn determines the pressure p1 in the canister through the action of the BPR. In the case of MoCl₅, it is possible to reduce the condensation temperature to room temperature or less, even without applying a diluent gas flow, as illustrated in the last example where the diluent gas flow is zero (i.e. corresponding to the embodiment of FIG. 1). For precursors such as HfCl₄, which have very low vapor pressure at room temperature, the diluent gas flow is regarded as necessary in order to bring down the condensation temperature to levels that are still greater than room temperature, but which nevertheless allow the supply line 10 towards the reactor to be maintained at lower temperatures than the temperature at which the vapor is produced, and which are low enough so as to be compatible with standard construction materials of the precursor injection systems in conventional reactors.

While example embodiments have been illustrated and described in detail in the drawings and foregoing description, such illustration and description are to be considered illustrative and not restrictive. Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

What is claimed is:

1. An apparatus for delivering a precursor to a reaction chamber, the apparatus comprising:
a recipient configured to hold a quantity of the precursor in a solid or liquid state at a given temperature and pressure so as to vaporize the precursor;
a carrier gas supply line, configured to supply a carrier gas to the recipient; and
a gas mixture transport line configured to transport a mixture of the carrier gas and a vapor of the precursor out of the recipient,
wherein the gas mixture transport line extends between the recipient and an outlet section of the gas mixture transport line,
wherein the outlet section is configured to be coupled to a supply line, external to the apparatus, configured to supply the mixture to the reaction chamber,
wherein the recipient and the gas mixture transport line are configured to be maintained at a predefined temperature, and
wherein the gas mixture transport line comprises a pressure control device configured to maintain the pressure upstream of the pressure control device at a predefined level.

2. The apparatus according to claim 1,
wherein the precursor is HfCl₄ or MoCl₅, and
wherein the carrier gas is Ar, He, or H₂.

3. The apparatus according to claim 1, wherein the apparatus comprises a furnace comprising the recipient, the gas mixture transport line and at least a portion of the carrier gas supply line.

4. The apparatus according to claim 1, further comprising a diluent gas supply line configured to supply a diluent gas to the gas mixture transport line, wherein the diluent gas supply line joins the gas mixture transport line at a location upstream of the pressure control device.

5. The apparatus according to claim 4, wherein the apparatus comprises a furnace comprising the recipient, the gas mixture transport line, at least a portion of the carrier gas supply line, and at least a portion of the diluent gas supply line.

6. The apparatus according to claim 1, wherein the pressure control device comprises a back pressure regulating valve.

7. The apparatus according to claim 1, wherein the recipient comprises a sublimation canister.

8. The apparatus according to claim 1, wherein the recipient comprises a bubbler.

9. An installation configured to deposit a layer on a substrate by chemically reacting a precursor with chemical elements of the substrate, wherein the installation comprises:
an apparatus for delivering the precursor to a reaction chamber, the apparatus comprising:
a recipient configured to hold a quantity of the precursor in a solid or liquid state at a given temperature and pressure so as to vaporize the precursor;
a carrier gas supply line, configured to supply a carrier gas to the recipient; and
a gas mixture transport line configured to transport a mixture of the carrier gas and a vapor of the precursor out of the recipient,
wherein the gas mixture transport line extends between the recipient and an outlet section of the gas mixture transport line,
wherein the outlet section is configured to be coupled to a supply line, external to the apparatus, configured to supply the mixture to the reaction chamber,
wherein the recipient and the gas mixture transport line are configured to be maintained at a predefined temperature, and
wherein the gas mixture transport line comprises a pressure control device configured to maintain the pressure upstream of the pressure control device at a predefined level; and
a secondary supply line coupled to the outlet section of the gas mixture transport line, wherein the secondary supply line is configured to transport a mixture of the carrier gas and the vapor of the precursor,
wherein the reaction chamber is coupled to the secondary supply line within a deposition reactor.

10. The installation according to claim 9,
wherein the precursor is HfCl₄ or MoCl₅, and
wherein the carrier gas is Ar, He, or H₂.

11. The installation according to claim 9, wherein the apparatus comprises: a furnace comprising the recipient, the gas mixture transport line, and at least a portion of the carrier gas supply line.

12. The installation according to claim 9, further comprising a diluent gas supply line configured to supply a diluent gas to the gas mixture transport line, wherein the diluent gas supply line joins the gas mixture transport line at a location upstream of the pressure control device.

13. The installation according to claim 12, wherein the apparatus comprises: a furnace comprising the recipient, the gas mixture transport line, at least a portion of the carrier gas supply line, and at least a portion of the diluent gas supply line.

14. The installation according to claim 9, wherein the pressure control device is a back pressure regulating valve.

15. The installation according to claim 9, wherein the recipient is a sublimation canister.

16. The installation according to claim 9, wherein the recipient is a bubbler.

17. A method for delivering a precursor to a reaction chamber, the method comprising:
heating the precursor in a recipient to a heating temperature, wherein the heating temperature is determined based on a pre-determined vapor pressure of the precursor;
vaporizing the precursor at the heating temperature;
supplying a predefined flow of a carrier gas to the recipient;
transporting a mixture of the carrier gas and the precursor away from the recipient through a gas mixture transport line while maintaining the gas mixture transport line at the heating temperature, wherein the gas mixture transport line comprises a pressure control device configured to maintain a pressure upstream of the pressure control device at a predefined level;
maintaining the pressure in the gas mixture transport line upstream of the pressure control device at the predefined level;
reducing a pressure of the mixture downstream of the pressure control device to a value less than the predefined level, thereby reducing a partial pressure of the precursor in the mixture; and
transporting the mixture towards the reaction chamber while maintaining the mixture at a temperature less than the heating temperature and greater than a condensation temperature of the precursor in the mixture.

18. The method according to claim 17, further comprising supplying a diluent gas flow at a location in the gas mixture transport line upstream of the pressure control device so that a diluted mixture flows through the device.

19. The method according to claim 17,
wherein the precursor is HfCl₄ or MoCl₅, and
wherein the carrier gas is Ar, He, or H₂.

20. The method according to claim 17, wherein the pressure control device is a back pressure regulating valve.
